(19) United States
(12) Patent Application Publication
(10) Pub. No.: US 2026/0287648 A1
(43) Pub. Date: Sep. 24, 2026

(54) TEST CIRCUIT AND SEMICONDUCTOR DEVICE INCLUDING THE TEST CIRCUIT

(71) Applicant: ABLIC INC., Nagano (JP)

(72) Inventor: Tsutomu TOMIOKA, Nagano (JP)

(21) Appl. No.: 19/543,582

(22) Filed: Feb. 18, 2026

(30) Foreign Application Priority Data
Mar. 18, 2025 (JP) 2025-043437

(51) Int. Cl. G01R 31/28

(52) U.S. Cl. CPC G01R 31/2884

(57) ABSTRACT

A test circuit is provided that reduces a threshold voltage shift due to BTI of an input transistor without consuming electric current, even in high-temperature environments. The circuit includes a PMOS transistor having a gate receiving a reference voltage, a source connected to a bulk transmitting a test signal from an input terminal, and a drain connected to a VSS terminal via a pull-down circuit. A diode serving as a backflow prevention circuit is connected between the input terminal and the source and bulk of the PMOS transistor to prevent signal backflow. Additionally, a diode serving as a clamp circuit is connected between the gate and the source and bulk of the PMOS transistor. The clamp circuit clamps a voltage drop of the bulk relative to the gate to a predetermined voltage.

### CROSS-REFERENCE TO RELATED APPLICATIONS

This application claims the priority of Japanese patent application No. 2025-043437, filed on Mar. 18, 2025, the entire contents of which are hereby incorporated herein by reference.

### BACKGROUND OF THE INVENTION

### 1. Field of the Invention

The present invention relates to a test circuit and a semiconductor device including the test circuit.

### 2. Description of the Related Art

In recent years, the scale and functionality of semiconductor integrated circuits have increased. Accordingly, a wide variety of technologies have been developed for evaluation and testing methods for the semiconductor integrated circuits. In the evaluation and testing methods, a test circuit is provided in a chip which forms the semiconductor integrated circuit. A test pin of a measuring apparatus, such as a semiconductor tester, is brought into contact with a test pad connected to the test circuit. Circuit characteristics and element characteristics in the semiconductor integrated circuit on the chip are thus measured (for example, see Japanese Patent Application Laid-open No. 2000-163998).

An operation of a related-art test circuit at the time of test mode entry and in a steady state is described with reference to FIG. 3 of Japanese Patent Application Laid-open No. 2000-163998. In the related-art test circuit, an output node CEH is at a low level (hereinafter referred to as “L level”) and a high level (hereinafter referred to as “H level”) at the time of test mode entry and in the steady state, respectively.

At the time of test mode entry, a voltage higher than a gate voltage VCP of a transistor (23) is supplied to an input terminal (16). When the voltage higher than the gate voltage VCP of the transistor (23) is supplied to the input terminal (16), gate-source voltages of a transistor (22) and the transistor (23) exceed a threshold voltage and the transistors turn ON. An electric current thus flows in from the input terminal (16). When this electric current becomes larger than a current value of a current limiting circuit (25), the voltage of a node n1 increases, and the output node CEH of an inverter (24) changes from the H level to the L level.

A threshold voltage VENT of the input terminal (16) for enabling entry into the test mode is expressed by Equation (1) below.

$$VENT = VCP + \vert Vthp \vert + Vthn + Vod \qquad ( 1 )$$

In the equation, Vthn is a threshold voltage of the transistor (22), Vthp is a threshold voltage of the transistor (23), and Vod is an overdrive voltage required to invert an output voltage of the inverter (24).

Meanwhile, in the steady state, a voltage lower than the threshold voltage VENT of the input terminal (16) is supplied. With the voltage to be supplied to the input terminal (16) being set to be lower than the threshold voltage VENT, the voltage of the node n1 is set to the L level and the voltage of the output node CEH of the inverter (24) is set to the H level.

However, the semiconductor integrated circuit including the related-art test circuit does not use the test circuit during the steady state operation. The input terminal (16) is thus often open or pulled down to a voltage Vss of a VSS terminal. When the input terminal (16) becomes open, the voltage of the input terminal (16) decreases to the voltage Vss due to the current limiting circuit (25), and source and bulk voltages of the transistor (23) also become the voltage Vss. A case in which the input terminal (16) is pulled down to the voltage Vss is similar to the case in which the input terminal (16) becomes open.

A positive voltage stress is applied between a gate and a bulk of the transistor (23) in a case in which a positive voltage (for example, a power supply voltage) is continuously applied to the voltage VCP supplied to the gate of the transistor (23) under a state in which the source and bulk voltages of the transistor (23) are at the voltage Vss. Accordingly, a threshold voltage shift due to bias temperature instability (BTI) may occur.

|Vthp| on the right side of Equation (1) above becomes larger in a case in which the threshold voltage shift due to BTI occurs. The threshold voltage VENT of the input terminal (16) also becomes larger. When the threshold voltage VENT of the input terminal (16) exceeds an absolute maximum rated voltage of the semiconductor integrated circuit because the threshold voltage shift due to BTI is excessive, VIN=VENT cannot be set. In this case, test mode entry cannot be performed. As described above, in the semiconductor integrated circuit including the related-art test circuit, the semiconductor integrated circuit is susceptible to the influence of the threshold voltage shift due to BTI in a case in which the semiconductor integrated circuit is expected to be used in a high-temperature environment. Accordingly, for example, a situation in which the test mode entry cannot be performed may occur at the time of a test after use in the high-temperature environment, such as at the time of evaluation after a reliability test assuming a product usage environment or at the time of analysis performed when a market failure occurs.

### SUMMARY OF THE INVENTION

The present invention has been made in consideration of the above-mentioned circumstances, and has an object to provide a test circuit capable of reducing a threshold voltage shift due to BTI of an input transistor without consuming electric current even in a case in which use in a high-temperature environment is expected, and also to provide a semiconductor device including the test circuit.

According to at least one embodiment of the present invention, there is provided a test circuit including an input transistor, a backflow prevention circuit, and a clamp circuit. The input transistor includes a gate to which a predetermined reference voltage is to be supplied, a source which is connected to a bulk of the input transistor and through which a test signal supplied from an input terminal is to be transmitted, and a drain connected to a ground terminal via a pull-down circuit. The backflow prevention circuit is connected between the input terminal and the source and the bulk of the input transistor, and is configured to prevent a backflow of the test signal to the input terminal. The clamp circuit is connected between the gate of the input transistor and the source and the bulk of the input transistor, and is configured to clamp a voltage drop of the bulk relative to the gate of the input transistor to a predetermined voltage. According to at least one embodiment of the present invention, there is also provided a semiconductor device including the test circuit.

According to the at least one embodiment of the present invention, it is possible to reduce the threshold voltage shift due to BTI of the input transistor without consuming electric current even in the case in which the use in a high-temperature environment is expected.

### BRIEF DESCRIPTION OF THE DRAWINGS

FIG. 1 is a schematic circuit diagram of a test circuit and a semiconductor device including the test circuit according to at least one embodiment of the present invention.

FIG. 2 is a circuit diagram for illustrating a configuration example of a voltage level shift circuit in the test circuit according to the at least one embodiment.

FIG. 3A and FIG. 3B are circuit diagrams for illustrating modification examples (second configuration example and third configuration example, respectively) of a current limiting circuit in the test circuit according to the at least one embodiment.

FIG. 4A and FIG. 4B are circuit diagrams for illustrating modification examples (second configuration example and third configuration example, respectively) of a clamp circuit in the test circuit according to the at least one embodiment.

FIG. 5A and FIG. 5B are circuit diagrams for illustrating modification examples (second configuration example and third configuration example, respectively) of a backflow prevention circuit in the test circuit according to the at least one embodiment.

FIG. 6A, FIG. 6B, and FIG. 6C are circuit diagrams for illustrating modification examples (second configuration example, third configuration example, and fourth configuration example, respectively) of a pull-down circuit in the test circuit according to the at least one embodiment.

### DESCRIPTION OF THE EMBODIMENTS

Now, a test circuit and a semiconductor device including the test circuit according to at least one embodiment of the present invention are described with reference to the attached drawings.

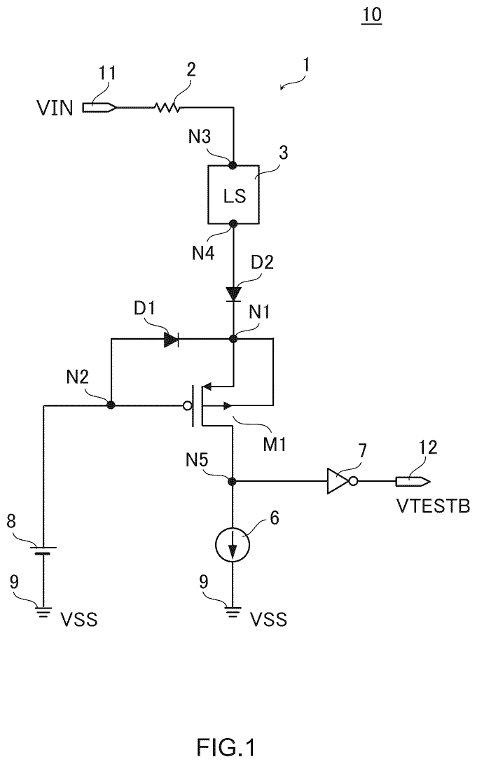

FIG. 1 is a schematic circuit diagram of a test circuit 1 which is an example of the test circuit according to the at least one embodiment, and a semiconductor device 10 including the test circuit 1 which is an example of the semiconductor device according to the at least one embodiment.

The test circuit 1 includes, for example, a PMOS transistor M1, a diode D2, and a diode D1. The PMOS transistor M1 serving as an input transistor includes, for example, a gate to which a predetermined reference voltage Vb1 is to be supplied by a reference voltage circuit 8, a source which is connected to the gate of the PMOS transistor M1 via the diode D1 and is connected to a bulk (substrate), and a drain connected to a VSS terminal 9 via a pull-down circuit 6. The VSS terminal 9 serving as a ground terminal supplies a voltage Vss serving as a reference for operations of the test circuit 1.

Herein, a connection point of the source and the bulk of the PMOS transistor M1 and a cathode of the diode D1 is referred to as “node N1,” and a connection point of the gate of the PMOS transistor M1 and an anode of the diode D1 is referred to as “node N2.”

The diode D2 serving as a backflow prevention circuit is connected in series between an input terminal 11 and the node N1. The diode D2 prevents an electric current from flowing in a reverse direction from the node N2 toward the input terminal 11 via the diode D1. Further, a voltage level shift circuit (indicated as “LS” in FIG. 1) 3 and a resistor 2 serving as a current limiting circuit are optionally connected. In the test circuit 1 illustrated as an example in FIG. 1, the resistor 2, the voltage level shift circuit 3, and the diode D2 are connected in the stated order from the input terminal 11 side positioned on the upstream side. The resistor 2 is a current limiting element connected to more reliably prevent latch-up. The latch-up may occur when a forward current flows through the diode D2 in a general CMOS process because an electric current flows through a parasitic bipolar transistor including the diode D2.

A node N5 which is a connection point between the PMOS transistor M1 and the pull-down circuit 6 is connected to an output terminal 12 via an inverter 7. The pull-down circuit 6 is formed of, for example, a constant current source that sinks a constant current Ib1.

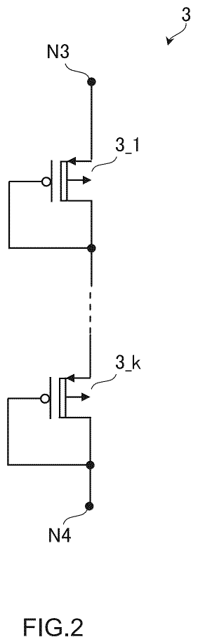

FIG. 2 is a circuit diagram for illustrating a configuration example of the voltage level shift circuit 3 in the test circuit 1. The voltage level shift circuit 3 includes “k” (natural number) diode-connected PMOS transistors 3_1, . . . , and 3_k connected in series. In the voltage level shift circuit 3, a node N3 which is the same node as a source of the PMOS transistor 3_1 corresponds to an input end of the voltage level shift circuit 3. A node N4 which is the same node as a gate and a drain of the PMOS transistor 3_k corresponds to an output end of the voltage level shift circuit 3.

In a case in which a threshold voltage of each of the PMOS transistors 3_1, . . . , and 3_k is represented by |Vthp3|, a voltage across both ends of the voltage level shift circuit 3 (between the node N3 and the node N4) is k times the threshold voltage (=k·|Vthp3|). A gate and a drain of the PMOS transistor 3_1 become the same node as the node N4 in the case of k=1.

Next, an operation of the test circuit 1 is described with the operation being divided into a period at the time of test mode entry and a period in a steady state. In the following, the operation of the test circuit 1 illustrated as an example in FIG. 1 is described assuming that a case in which a voltage level of a voltage VTESTB of the output terminal 12 is a low level (hereinafter referred to as “L level”) is defined as the period at the time of test mode entry, and a case in which the voltage level of the voltage VTESTB is a high level (hereinafter referred to as “H level”) is defined as the period in the steady state.

### At Time of Test Mode Entry: In Case of Voltage VTESTB=L Level

With consideration given in the same manner as in Equation (1) above, a condition under which a threshold voltage VENT of the input voltage VIN for causing the transition from a normal mode to a test mode becomes larger than a constant current Ib1 flowing in from the input terminal 11 can be expressed by Equation (2) below through use of a reference voltage Vb1, a threshold voltage |Vth(M1)| of the PMOS transistor M1, a forward voltage Vf(D2) of the diode D2, a voltage drop V(LS) of the voltage level shift circuit 3, a voltage drop V(2) of the resistor 2, and an overdrive voltage Vod required to invert the output voltage of the inverter 7.

$$VIN \geq VENT = Vb 1 + \vert Vth ( M 1 ) \vert + Vf ( D 2 ) + V ( LS ) + V ( 2 ) + Vod \qquad ( 2 )$$

A difference between Equation (2) above and Equation (1) above resides in that the forward voltage Vf(D2) of the diode D2 is included and the voltage drop V(2) of the resistor 2 is also included, instead of the threshold voltage Vthn of the NMOS transistor. In this case, the threshold voltage Vthn and the forward voltage Vf(D2) have the same order which is from about 0.6 V to about 0.7 V at a temperature of about 25° C. (room temperature). Further, the diode D1 has a reverse bias in a case in which Equation (2) above is satisfied. An electric current thus does not flow through the diode D1.

### In Steady State: In Case of Voltage VTESTB=H Level

Based on Equation (2) above, in the case of VIN<VENT, the input voltage of the inverter 7, that is, a voltage of the node N5, decreases owing to the constant current Ib1 flowing through the pull-down circuit 6. The voltage VTESTB of the output terminal 12 becomes the H level when the voltage of the node N5 is the L level. In a case in which the voltage VTESTB of the output terminal 12 is the H level, a voltage drop of the bulk relative to the gate of the PMOS transistor M1 is clamped to a forward voltage Vf(D1) of the diode D1. The voltage of the bulk of the PMOS transistor M1 is thus a voltage that has dropped by the forward voltage Vf(D1) of the diode D1 from a voltage VN2 of the node N2.

The forward voltage of the diode serving as a predetermined voltage becomes as small as 0.5 V or less in a high-temperature environment exceeding, for example, 100° C. Accordingly, a voltage stress causing BTI can be suppressed to be small. In a case in which the input voltage VIN is pulled down to the voltage Vss, because the reference voltage Vb1 is larger than the input voltage VIN (Vb1>VIN), an electric current flowing from the node N2 toward the input terminal 11 via the diode D1 in a forward direction of the diode D1 is cut off owing to a reverse characteristic (reverse bias characteristic) of the diode D2. Accordingly, the threshold voltage shift of the PMOS transistor M1 due to BTI can be reduced without consuming electric current.

The test circuit and the semiconductor device according to the at least one embodiment described above are configured by connecting the clamp circuit between the gate of the input transistor and the source and the bulk of the input transistor and connecting the voltage level shift circuit and the backflow prevention circuit between the input terminal and the source and the bulk of the input transistor. The test circuit and the semiconductor device according to the at least one embodiment configured as described above can limit the voltage drop of the bulk relative to the gate of the input transistor with the clamp circuit, and can cut off a backflow current flowing toward the input terminal in a case in which the voltage of the input terminal decreases, with the backflow prevention circuit. The threshold voltage shift of the input transistor due to BTI can thus be reduced without consuming electric current.

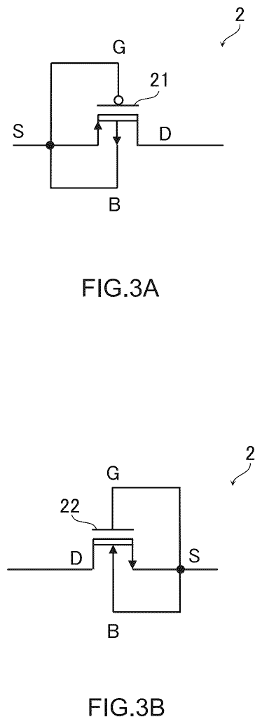

The resistor 2, the diodes D1 and D2, and the pull-down circuit 6 in the above-mentioned test circuit 1 and semiconductor device 10 are not limited to those in the example illustrated in FIG. 1. The resistor 2, the diodes D1 and D2, and the pull-down circuit 6 may be modified and applied as illustrated in FIG. 3A to FIG. 6C referred to later.

Subsequently, modification examples of the resistor 2, the diode D1, the diode D2, and the pull-down circuit 6 are described with reference to FIG. 3A to FIG. 6C.

FIG. 3A is a circuit diagram for illustrating a depletion-type PMOS transistor 21 serving as a modification example (second configuration example) of the resistor 2. FIG. 3B is a circuit diagram for illustrating a depletion-type NMOS transistor 22 serving as another modification example (third configuration example) of the resistor 2. Symbols G, S, D, and B indicated in the figures correspond to a gate, a source, a drain, and a bulk, respectively.

The resistor 2 may be, for example, instead of a resistive element which is a first configuration example, a current source of the depletion-type PMOS transistor 21 with the gate G, the source S, and the bulk B being connected thereto (see FIG. 3A), or may be a current source of the depletion-type NMOS transistor 22 with the gate G, the source S, and the bulk B being connected thereto (see FIG. 3B). In a case in which the PMOS transistor 21 is applied, the PMOS transistor 21 is connected so that the source S is on the input terminal 11 side and the drain D is on the diode D2 side. In a case in which the NMOS transistor 22 is applied, the NMOS transistor 22 is connected so that the drain D is on the input terminal 11 side and the source S is on the diode D2 side.

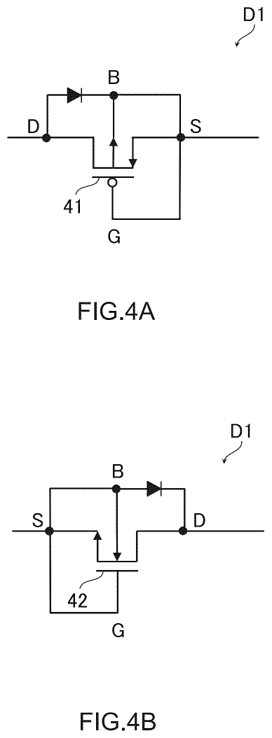

FIG. 4A is a circuit diagram for illustrating a PMOS transistor 41 serving as a modification example (second configuration example) of the diode D1. FIG. 4B is a circuit diagram of an NMOS transistor 42 serving as another modification example (third configuration example) of the diode D1.

The diode D1 may be, for example, instead of a diode element which is a first configuration example, the PMOS transistor 41 with the gate G, the source S, and the bulk B being connected (see FIG. 4A), or may be the NMOS transistor 42 with the gate G, the source S, and the bulk B being connected (see FIG. 4B). In the PMOS transistor 41, a parasitic diode between the drain D and the bulk B functions as the diode D1. In the NMOS transistor 42, a parasitic diode between the bulk B and the drain D functions as the diode D1.

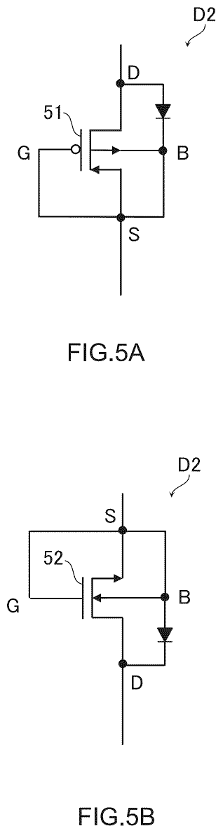

FIG. 5A is a circuit diagram for illustrating a PMOS transistor 51 serving as a modification example (second configuration example) of the diode D2. FIG. 5B is a circuit diagram of an NMOS transistor 52 serving as another modification example (third configuration example) of the diode D2.

The diode D2 may be, for example, instead of a diode element which is a first configuration example, the PMOS transistor 51 with the gate G, the source S, and the bulk B being connected (see FIG. 5A), or may be the NMOS transistor 52 with the gate G, the source S, and the bulk B being connected (see FIG. 5B). In the PMOS transistor 51, a parasitic diode between the drain D and the bulk B functions as the diode D2. In the NMOS transistor 52, a parasitic diode between the bulk B and the drain D functions as the diode D2.

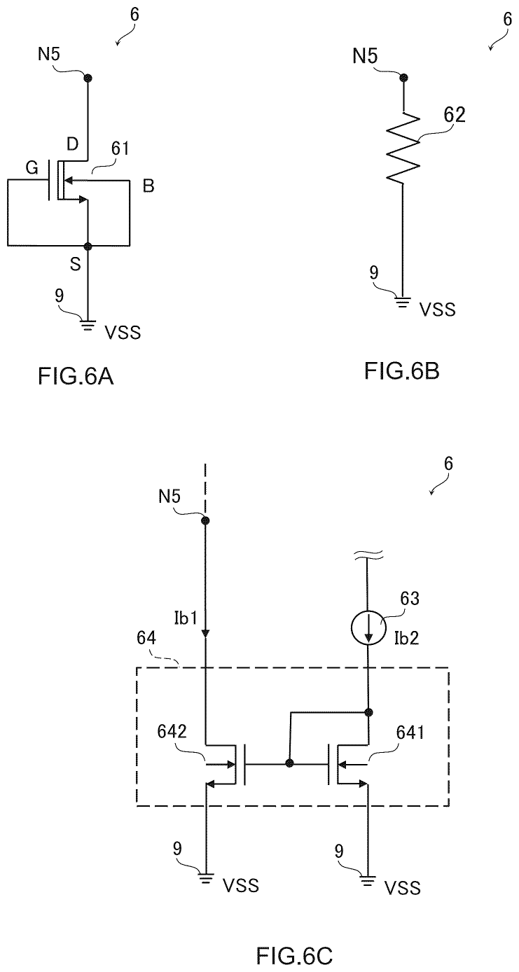

FIG. 6A is a circuit diagram of a depletion-type NMOS transistor 61 serving as a modification example (second configuration example) of the pull-down circuit 6. FIG. 6B is a circuit diagram of a resistive element 62 serving as another modification example (third configuration example) of the pull-down circuit 6. FIG. 6C is a circuit diagram of a constant current source 63 and a current mirror circuit 64 serving as a further another modification example (fourth configuration example) of the pull-down circuit 6.

The pull-down circuit 6 may be, instead of a constant current source (first configuration example) that sinks the constant current Ib1, the depletion-type NMOS transistor 61 with the gate G, the source S, and the bulk B being connected (see FIG. 6A). In a case in which the NMOS transistor 61 is applied as the pull-down circuit 6, the drain D is connected to the node N5, and the gate G, the source S, and the bulk B are connected to the VSS terminal 9. Further, the pull-down circuit 6 may be the resistive element 62 including a first end connected to the node N5 and a second end connected to the VSS terminal 9 (see FIG. 6B).

Moreover, the pull-down circuit 6 may include the constant current source 63 that sinks a constant current Ib2 to the VSS terminal 9, and the current mirror circuit 64. The current mirror circuit 64 includes an NMOS transistor 641 that receives the constant current Ib2 at a drain and a gate thereof, and an NMOS transistor 642 that causes the constant current Ib1 (=m·Ib2) obtained by copying the constant current Ib2 by a predetermined mirror ratio “m” (“m” is any positive number) to flow into a drain thereof, that is, the node N5 (see FIG. 6C).

The present invention is not limited to the at least one embodiment described above, and can be carried out in various forms in addition to the at least one embodiment described above in the stage of carrying out the invention, and various omissions, additions, replacements, or alterations may be made thereto without departing from the gist of the invention. For example, in the above-mentioned test circuit 1 and semiconductor device 10, the voltage level shift circuit 3 is connected between the resistor 2 and the diode D2. However, a connection location of the voltage level shift circuit 3 and the number of voltage level shift circuits 3 to be connected are not limited to those described above. In a case in which the voltage level shift circuit 3 is connected, at least one voltage level shift circuit 3 is only required to be connected between the input terminal 11 and the node N1. A position of the voltage level shift circuit 3 and the number of voltage level shift circuits 3 are freely set.

In the above-mentioned test circuit 1 and semiconductor device 10, the case in which the resistor 2 is applied as the current limiting circuit has been described, but the resistor 2 may be applied as the voltage level shift circuit 3. In the above-mentioned test circuit 1 and semiconductor device 10, the case in which the diode D2 is applied as the backflow prevention circuit has been described, but the diode D2 may be applied as the backflow prevention circuit also serving as the voltage level shift circuit 3.

The at least one embodiment and modifications thereof described above are encompassed in the scope and the gist of the invention, and are encompassed in the invention defined in the appended claims and equivalents thereof.

What is claimed is:

1. A test circuit, comprising:
an input transistor including a gate to which a predetermined reference voltage is to be supplied, a source which is connected to a bulk of the input transistor and through which a test signal supplied from an input terminal is to be transmitted, and a drain connected to a ground terminal via a pull-down circuit;
a backflow prevention circuit connected between the input terminal and the source and the bulk of the input transistor, the backflow prevention circuit being configured to prevent a backflow of the test signal to the input terminal; and
a clamp circuit connected between the gate of the input transistor and the source and the bulk of the input transistor, the clamp circuit being configured to clamp a voltage drop of the bulk relative to the gate of the input transistor to a predetermined voltage.

2. The test circuit according to claim 1, further comprising a current limiting circuit connected in series between the input terminal and the backflow prevention circuit.

3. The test circuit according to claim 1, further comprising at least one voltage level shift circuit out of a first voltage level shift circuit connected in series between the input terminal and the backflow prevention circuit and a second voltage level shift circuit connected in series to the backflow prevention circuit and the source and the bulk of the input transistor.

4. The test circuit according to claim 3, wherein the at least one voltage level shift circuit includes one of one diode-connected PMOS transistor or a plurality of diode-connected PMOS transistors connected in series.

5. The test circuit according to claim 2, further comprising at least one voltage level shift circuit out of a first voltage level shift circuit connected in series between the input terminal and the current limiting circuit, a second voltage level shift circuit connected in series between the current limiting circuit and the backflow prevention circuit, and a third voltage level shift circuit connected in series to the backflow prevention circuit and the source and the bulk of the input transistor.

6. The test circuit according to claim 5, wherein the at least one voltage level shift circuit includes one of one diode-connected PMOS transistor or a plurality of diode-connected PMOS transistors connected in series.

7. The test circuit according to claim 1, wherein the backflow prevention circuit includes a diode including an anode configured to receive the test signal and a cathode configured to supply the test signal.

8. The test circuit according to claim 7, wherein the diode is a PMOS transistor including a drain corresponding to the anode and a gate, a source, and a bulk corresponding to the cathode, or an NMOS transistor including a drain corresponding to the cathode and a gate, a source, and a bulk corresponding to the anode.

9. The test circuit according to claim 1,
wherein the clamp circuit includes a diode including an anode connected to the gate of the input transistor and a cathode connected to the source and the bulk of the input transistor, and
wherein the predetermined voltage is a forward voltage of the diode.

10. The test circuit according to claim 9, wherein the diode is a PMOS transistor including a drain corresponding to the anode and a gate, a source, and a bulk corresponding to the cathode, or an NMOS transistor including a drain corresponding to the cathode and a gate, a source, and a bulk corresponding to the anode.

11. A semiconductor device, comprising the test circuit of claim 1.
